(19) United States
(12) Patent Application Publication
(10) Pub. No.: US 2007/0264760 A1
(43) Pub. Date: Nov. 15, 2007

(54) Method of forming a memory cell array

(76) Inventor: Martin Roessiger, Dresden (DE)

Correspondence Address: EDELL, SHAPIRO & FINNAN, LLC, 1901 RESEARCH BLVD., SUITE 400, ROCKVILLE, MD, 20850, US

(21) Appl. No.: 11/433,769

(22) Filed: May 15, 2006

(51) Int. Cl. H01L 21/8232

(52) U.S. Cl. 438/142

(57) ABSTRACT

A semiconductor substrate is provided. A plurality of first conductive lines is formed, followed by forming a plurality of second conductive lines above the first conductive lines. Memory cells are at least partially formed in the semiconductor substrate. Thereafter, at least one of the second conductive lines is removed, thereby forming an opened portion. A sacrificial material is filled into the opened portion and a first hardmask layer is provided. The first hardmask layer is patterned so as to form a pattern comprising lines and spaces, so that portions of the sacrificial material are uncovered. Thereafter, the uncovered portions of the sacrificial material are selectively etched, thereby forming contact openings. Finally, a conductive material is filled into the contact openings and a plurality of third conductive lines connected with the contact openings is provided.

### FIELD OF THE INVENTION

The invention relates to a method of forming a memory cell array.

### BACKGROUND OF THE INVENTION

A semiconductor memory cell array typically comprises a plurality of memory cells that are arranged in rows and columns. Moreover, such a memory cell array comprises a plurality of bitlines and a plurality of wordlines, e.g., the gate electrodes of rows of memory cell transistors are connected by wordlines, by which the memory cells are to be addressed.

An example of a non-volatile memory device is based on the NROM technology. FIG. 1 shows an example of a cross-sectional view of an NROM cell between line III-III denoted in FIG. 3. In particular, the NROM cell is an N-channel MOSFET device, wherein the gate dielectric is replaced with a storage layer stack 21. As is shown in FIG. 1, the storage layer stack 21 is disposed above the channel 25 and under the gate electrode 24. The storage layer stack 21 comprises a silicon nitride layer 212 which stores the charge and two insulating silicon dioxide layers 211, 213 which sandwich the silicon nitride layer 212. The silicon dioxide layers 211, 213 have a thickness greater larger 2 nm to avoid any direct tunnelling. In the NROM cell shown in FIG. 1 two charges 23 are stored at each of the edges adjacent to the n-doped source/drain regions 41, 42.

In a memory cell array comprising a plurality of memory cells of the type shown in FIG. 1, the bitlines are implemented as doped portions 41, 42. In other words, segments of the bitlines form the first and second source/drain regions 41, 42 of a corresponding memory cell. Moreover, segments of the wordlines form the gate electrode 24 of a corresponding memory cell. The NROM cell is programmed by channel hot electron injection (CHE), for example, whereas erasing is accomplished by hot hole enhanced tunnelling (HHET) by applying appropriate voltages to the corresponding bitlines and wordlines, respectively. Due to the charge trapped in the charge storage layer, the threshold voltage of the transistor is changed. By applying appropriate voltages to the corresponding wordlines and bitlines, the changed threshold voltage and, thus, the stored information, is detected.

Since, as has been described above, the bitlines are implemented as n-doped substrate portions, the problem arises that the resistance of the bitlines is comparatively high. Accordingly, usually metal bitlines (not shown in this drawing) are provided, the metal bitlines being arranged in a higher metallization layer above the semiconductor substrate 1 and the gate electrodes 24. Each single bitline is connected with the supporting metal bitline at predetermined distances by a bitline contact.

Conventionally, these bitline contacts have been formed by removing predetermined wordlines and defining a bitline contact using a mask having a hole pattern so as to define a contact opening at a predetermined position of the wordline removal region. In a later process step, the contact opening is filled with a conductive material, followed by the step of providing the supporting bitlines which are made of a metal. The supporting bitlines are in contact with the conductive filling of the contact opening.

### SUMMARY

According to the present invention, an improved method of forming a memory cell array comprises: providing a semiconductor substrate having a surface, forming a plurality of first conductive lines running along a first direction; forming a plurality of second conductive lines above the first conductive lines, the second conductive lines running along a second direction, with the second direction intersecting the first direction; providing a plurality of memory cells, each being at least partially formed in the semiconductor substrate and each being accessible by addressing corresponding ones of the first and second conductive lines; removing at least one of the second conductive lines, thereby forming an opened portion that extends in the second direction; filling the opened portion with a sacrificial material; providing a first hardmask layer; patterning the first hardmask layer to form a pattern comprising lines and spaces, such that portions of the sacrificial material are uncovered; etching the uncovered portions of the sacrificial material selectively with respect to the first hardmask layer, thereby forming contact openings; filling a conductive material into the contact openings; and providing a plurality of third conductive lines connected to the contact openings.

The above and still further features and advantages of the present invention will become apparent upon consideration of the following detailed description of specific embodiments thereof, wherein like numerals define like components in the drawings.

### BRIEF DESCRIPTION OF THE DRAWINGS

FIG. 1A shows a cross-sectional view of an NROM cell;

FIG. 2 shows a plan view of a substrate comprising implanted bitlines;

FIG. 3 shows a plan view of a substrate comprising implanted bitlines as well as patterned wordlines;

FIG. 4 shows a plan view of the substrate shown in FIG. 3 after removing selected wordlines;

FIG. 5A shows a cross-sectional view of the substrate shown in FIG. 4;

FIG. 5B shows another cross-sectional view of the substrate shown in FIG. 4;

FIG. 6A shows a cross-sectional view of a substrate after performing a further processing step;

FIG. 6B shows another cross-sectional view of the substrate after performing another other processing step;

FIG. 6C shows another cross-sectional view of the substrate;

FIG. 6D shows another cross-sectional view of the substrate;

FIG. 7A shows a plan view of the substrate shown in FIG. 6;

FIG. 7B shows a plan view of the substrate according to a further embodiment;

FIG. 8A shows a cross-sectional view of the substrate after performing another processing step;

FIG. 8B shows another cross-sectional view of the substrate;

FIG. 9 shows a cross-sectional view of the substrate after performing a further processing step;

FIG. 10 shows a plan view of the resulting memory cell array.

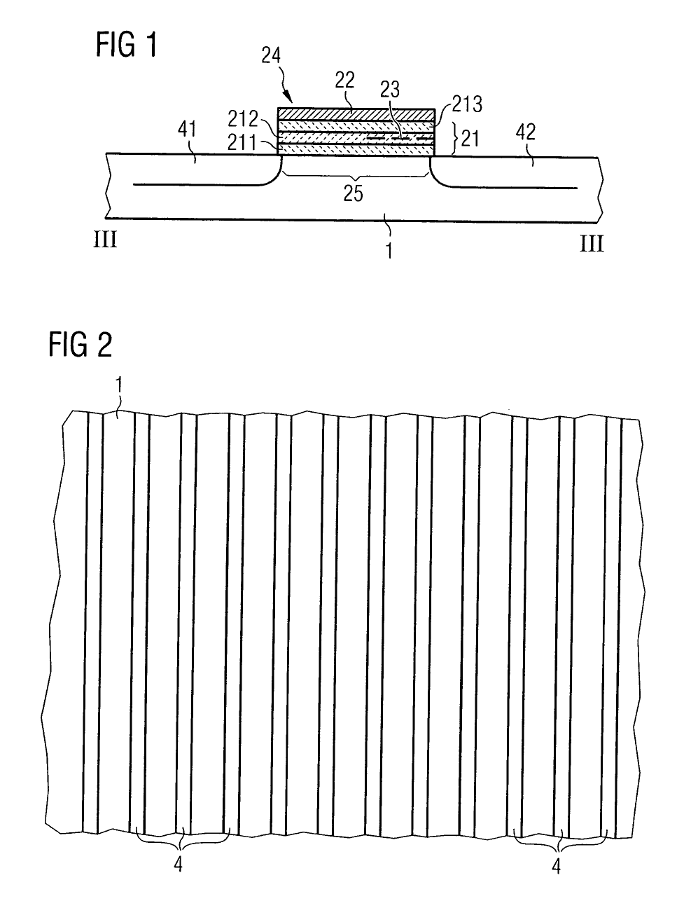

### DETAILED DESCRIPTION OF THE INVENTION

The accompanying drawings are included to provide a further understanding of the present invention and are incorporated in and constitute a part of this specification. The drawings illustrate the embodiments of the present invention and together with a description serve to explain the principles of the invention. Other embodiments of the present invention and many of the intended advantages of the present invention will be readily appreciated, as will become better understood by reference to the following detailed description. The elements of the drawings are not necessarily to scale relative to each other. Like reference numerals designate corresponding similar parts.

As will be described hereinafter, the method of forming a memory cell array according to the present invention comprises providing a semiconductor substrate having a surface, forming a plurality of first conductive lines, the first conductive lines running along a first direction, forming a plurality of second conductive lines above the first conductive lines, the second conductive lines running along a second direction, the second direction intersecting the first direction, providing a plurality of memory cells, each of the memory cells being at least partially formed in the semiconductor substrate, each of the memory cells being accessible by addressing corresponding ones of the first and second conductive lines, removing at least one of the second conductive lines, thereby forming an opened portion, the opened portion extending in the second direction, filling a sacrificial material into the opened portion, providing a first hardmask layer, patterning the first hardmask layer so as to form a pattern comprising lines and spaces, so that portions of the sacrificial material are uncovered, etching the uncovered portions of the sacrificial material selectively with respect to the first hardmask layer thereby forming contact openings, filling a conductive material into the contact openings, and providing a plurality of third conductive lines connected with the contact openings.

As defined above, the first hardmask layer is patterned so as to form a pattern comprising lines and spaces, e.g., by patterning a photoresist layer using a photomask having a lines/spaces pattern. After correspondingly developing the photoresist material, the lines/spaces pattern is transferred into the first hardmask layer by a suitable etching step. As an alternative, the photoresist layer can be patterned using a photomask having a pattern comprising elongated holes so that in sections a lines/spaces pattern is generated in the photoresist layer, e.g., the pattern comprising elongated holes can have a ratio of hole length to hole width of approximately 5:1 to 1000:1, for example 9:1 to 500:1.

For example, the removal of at least one of the second conductive lines may be accomplished by providing a second hardmask layer covering the second conductive lines, patterning the second hardmask layer so that the at least one of the second conductive lines is uncovered, and performing an etching step so as to remove the at least one of the second conductive lines.

As is used herein, the terms “first” and “second” hardmask layer do not imply any order in which these hardmask layers are to be deposited. These terms are only used in order to distinguish these layers from each other.

In particular, the first and the second hardmask layers can be made from the same material. Nevertheless, any arbitrary first and second hardmask layers can be used. However, the sacrificial material should be a material which can be etched selectively with respect to the material of the first and second hardmask layers. In addition, the material of the second conductive lines should be a material which can be etched selectively with respect to the second hardmask layer. By way of example, the material of the first hardmask comprises silicon nitride. Moreover, for example, the sacrificial material comprises silicon dioxide.

For example, the first conductive lines correspond to bit lines and the second conductive lines correspond to word lines of the memory cell array.

By way of example, each of the memory cells comprises a transistor comprising a first and a second source/drain regions, a channel, a gate electrode and a storage layer disposed between the channel and the gate electrode. In particular, each of the first and second source/drain regions may form part of a corresponding first conductive line, and each of the gate electrodes may form part of a corresponding second conductive line.

The plurality of first conductive lines can be provided by providing a covering layer on the substrate surface, patterning the covering layer using a bitline mask having a lines/spaces pattern so that lines of the substrate surface are uncovered, and performing an ion implantation step so as to dope the uncovered lines of the substrate. For example, the bitline mask is used for patterning the first hardmask layer so as to form the lines/spaces pattern. Thereby, the special advantage is obtained that no additional mask for defining the contact openings is necessary. Moreover, due to the use of the same mask and the same illumination scheme, the overlay of the contact openings and the bitlines can be improved.

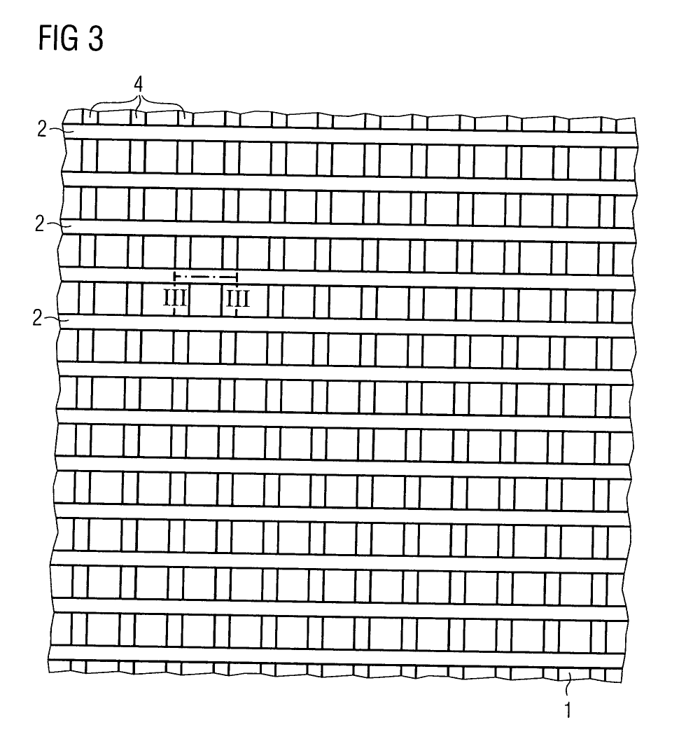

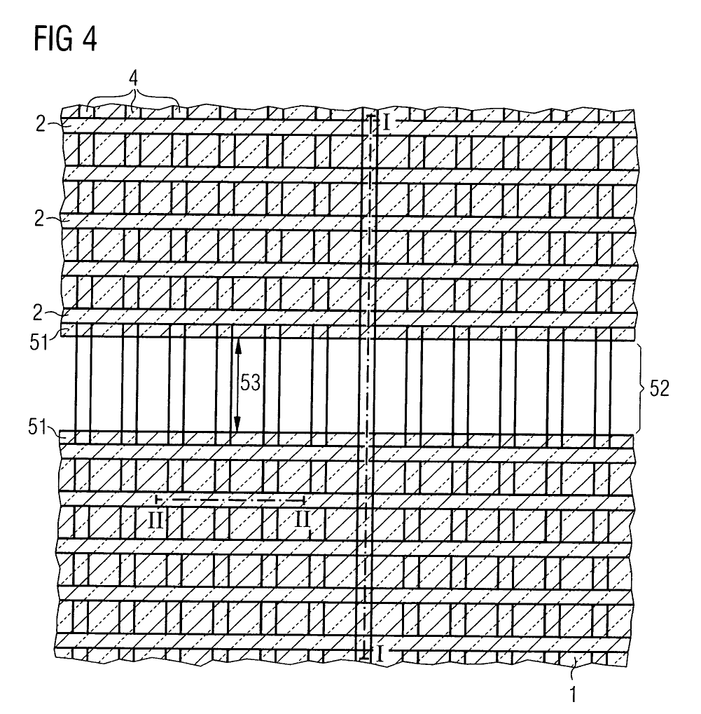

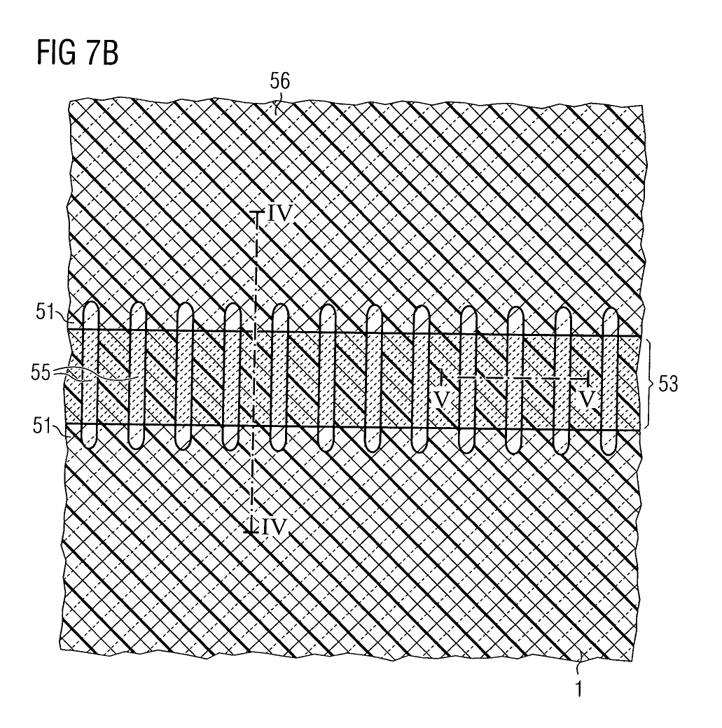

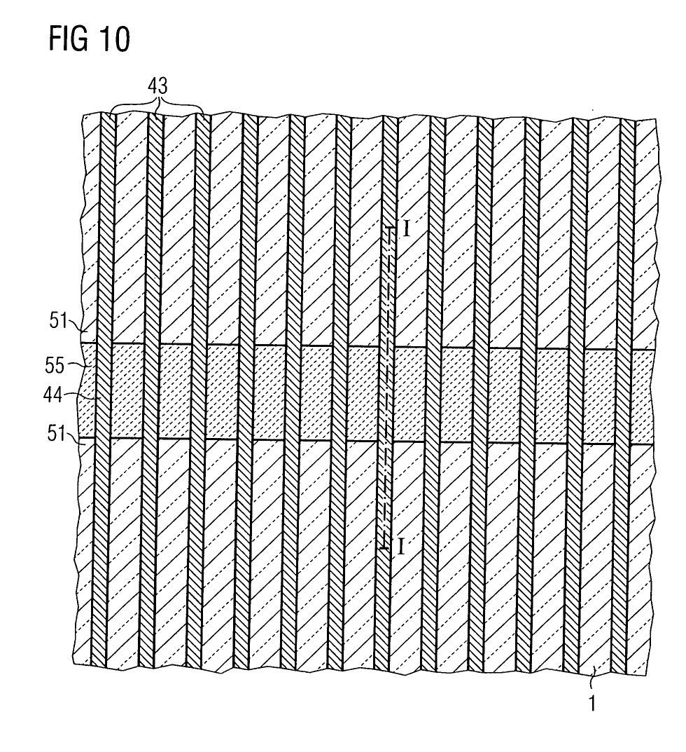

In the following cross-sectional views the views are taken along different cross-sections, as can for example be seen from FIG. 3, FIG. 4, FIG. 7, and FIG. 10.

The method begins with providing a semiconductor substrate, in particular, a silicon substrate, which is preferably p-doped. In a first step, a storage layer stack comprising a first SiO₂ layer having a thickness of 1.5 to 10 nm, a Si₃N₄ layer having a thickness of 2 to 15 nm followed by a second SiO₂ layer having a thickness of 5 to 15 nm is deposited. Thereafter, the storage layer stack is patterned so as to form lines. The lines are covered with a protective layer and spacers adjacent to the sidewalls of the lines of the storage layer stack are formed. In the next step, first and second source/drain regions are defined by performing an ion implantation step. In particular, a photoresist material is deposited and patterned using a mask having a lines/spaces pattern, so that the resulting photoresist pattern also has a lines/spaces pattern. An ion implantation step is performed using n-dopants so as to define the first and second source/drain regions 41, 42 or bitlines 4, respectively. In particular, the n-dopants are implanted into the exposed substrate portions, i.e., the spaces between adjacent lines of the photoresist material.

A plan view of the resulting structure is shown in FIG. 2, which shows a plurality of bitlines 4 which are at least partially formed in a semiconductor substrate 1. For example, the bitlines 4 can have a width of less than 150 nm, in particular, less than 100 nm, for example, less than 80 nm and have a distance between adjacent bitlines of less than 150 nm, in particular, less than 100 nm, for example, less than 80 nm. However, the width of the bitlines 4 can be equal to or different from the distance between adjacent bitlines.

In the next step, a bitline oxide is provided by performing a silicon dioxide deposition step, followed by a step of depositing a wordline layer stack. For example, the wordline layer stack may comprise a tungsten layer having a thickness of approximately 60 nm, followed by a silicon dioxide layer having a thickness of approximately 120 nm. For example, the silicon dioxide layer may be formed by a chemical vapour deposition method, using TEOS (tetraethylorthosilicate) as a starting material.

The silicon dioxide layer may, for example, act as a cap layer of the wordlines to be formed. In the next step, the wordline layer stack is patterned using a mask having a lines/spaces pattern so as to form single word lines 2. The resulting structure is shown in FIG. 3.

As can be seen in FIG. 3, a plurality of bitlines 4 are formed, the bitlines 4 extending in a first direction, and a plurality of wordlines 2 are formed, the wordlines 2 extending in a second direction which is perpendicular to the first direction. The width of each of the word lines may be approximately less than 150 nm, in particular, less than 100 nm and, for example, less than 80 nm. Likewise, the distance between adjacent wordlines may be approximately less than 150 nm, in particular, less than 100 nm and, for example, less than 80 nm. The width of each of the wordlines may be equal to or different from the distance between adjacent wordlines.

In the next step, a silicon nitride bottom hardmask layer 51 is deposited, the silicon nitride hardmask layer 51 having a thickness of approximately 30 to 100 nm. The silicon nitride bottom hardmask 51 is patterned so as to form an opening by which at least one of the wordlines 2 is uncovered. Accordingly, a wordline removal region 52 is defined. In the next step, an etching step is performed so as to completely remove the uncovered wordline(s). As a result, the structure shown in FIG. 4 is obtained.

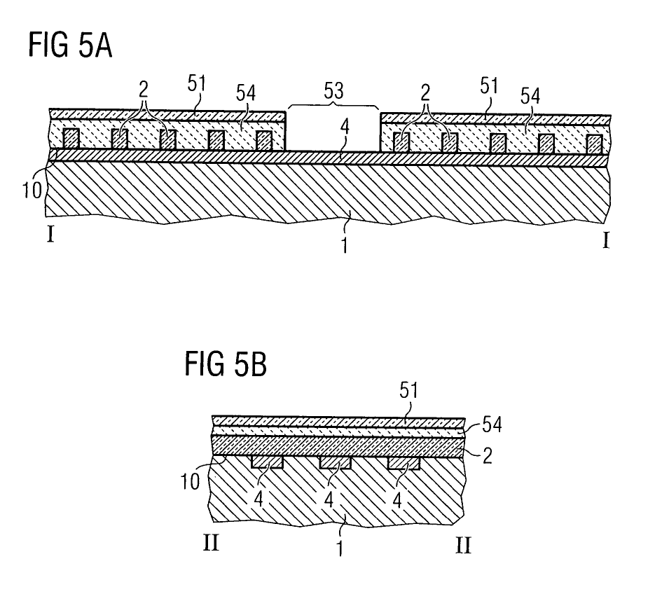

As can be seen in FIG. 4, a selected one of the wordlines 2 is removed, thereby forming an opened portion 53 between adjacent portions of the silicon nitride hardmask layer 51. FIG. 5A shows a cross-sectional view of the obtained substrate between I and I referenced in FIG. 4. In FIG. 5A, in the surface portion of the semiconductor substrate 1, a first or second source/drain region 41, 42 is formed. In particular, the first or second source/drain region 41, 42 is adjacent to the surface 10 of the substrate. A plurality of wordlines 2 is disposed perpendicularly with respect to the plane of the drawing. Adjacent wordlines 2 are insulated from each other by a planarizing layer 54 made of an insulating material such as BPSG (Boron-Doped Phosphosilicate Glass) or others. A silicon nitride hardmask layer 51 is deposited on top of the planarizing layer 54 and patterned so as to form an opened portion 53. Due to the opened portion 53 a part of the semiconductor substrate 1 is exposed.

FIG. 5B shows a cross-sectional view of the substrate between II and II referenced in FIG. 4. In particular, the cross-sectional view shown in FIG. 5B is taken along a wordline 2. As shown, buried bitlines 4 are formed perpendicularly with respect to the plane of the drawing. The buried bitlines 4 act as the first and second source/drain regions of the storage transistors to be formed. On top of the substrate surface 10, the wordline 2 is formed, followed by the planarizing layer 54. On top of the planarizing layer 54, the silicon nitride hardmask 51 is formed.

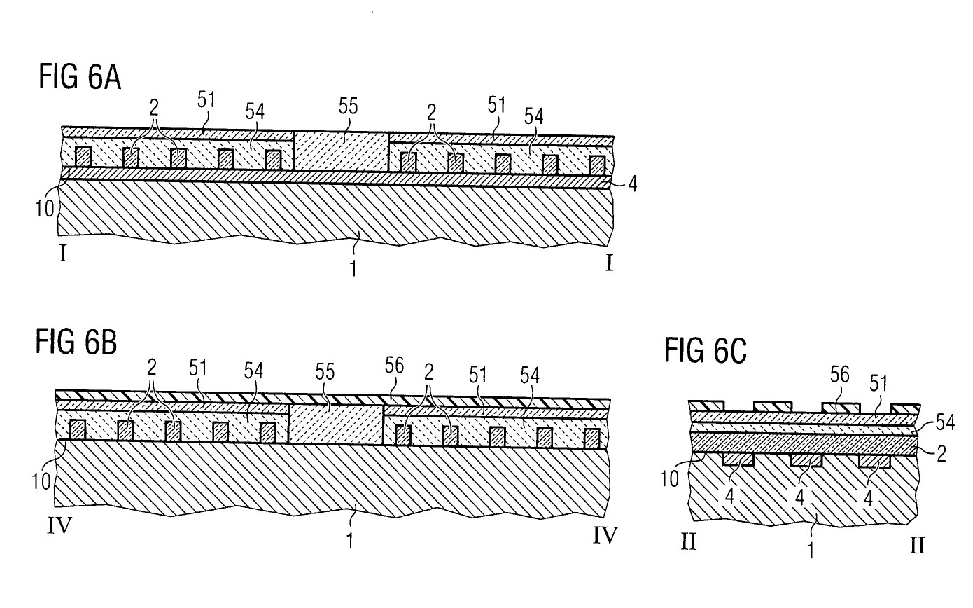

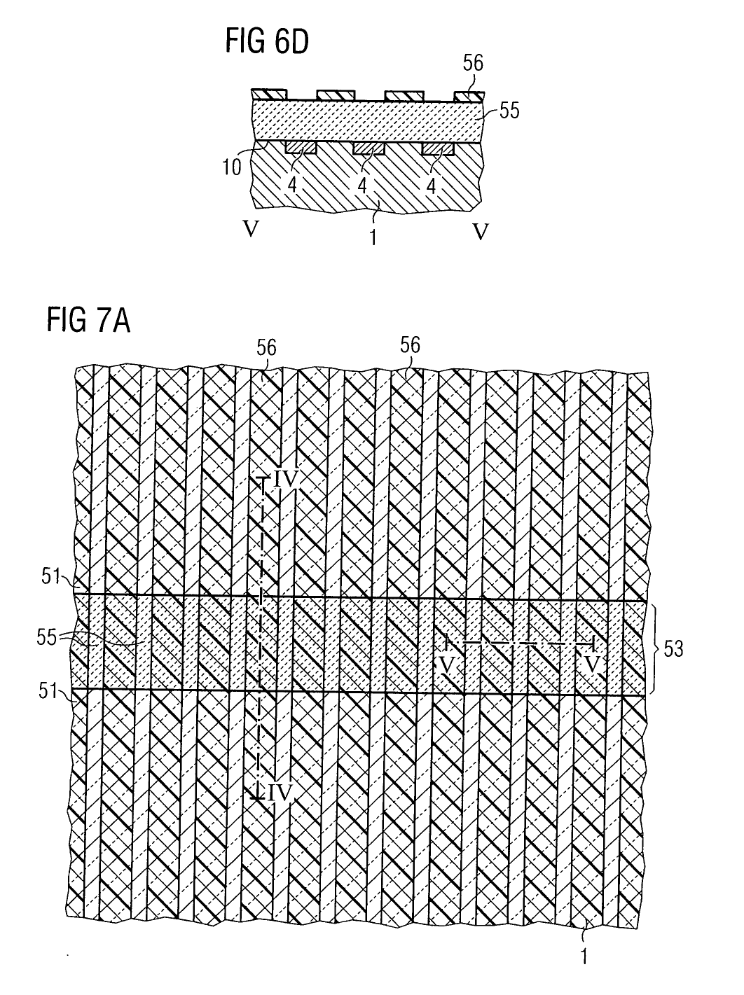

In the next step, a sacrificial material such as silicon dioxide 55 is filled into the opened portion 53. For example, a silicon dioxide layer may be deposited, followed by a CMP (chemical mechanical polishing) step or by a back-etching step, so that as a result a planarized surface is obtained. The resulting structure is for example shown in FIG. 6A, showing a cross-sectional view between I and I. As shown, the opened portion 53 is completely filled with the silicon dioxide material 55. In the next steps, a top hardmask layer 56, which can again be made of silicon nitride is deposited on the resulting surface, followed by a patterning step. The top hardmask layer 56 can have a thickness of 30 to 100 nm. In particular, during the patterning step, a photoresist material which is deposited on top of the silicon nitride hardmask material 56 is patterned using a mask having a pattern comprising lines and spaces. Advantageously, in this step, the lines/spaces mask for defining the buried bitlines 4 can be used. The advantage of using this particular mask is because thereby a very good overlay can be obtained. To be more specific, the overlay of the mask in the direction of the wordlines is very good since the same mask and the same illumination scheme which has been used for defining the bitlines is also used.

As a result, a substrate having the cross-sectional view shown in FIG. 6B is obtained. In particular, FIG. 6B shows a cross-sectional view between IV and IV as can also be seen from FIG. 7. The cross-sectional view shown in FIG. 6B is taken between adjacent bitlines. Accordingly, in FIG. 6B no doped region 4 is shown. On top of the planarizing layer 54, the patterned silicon nitride hardmask 51 is disposed, followed by the silicon nitride hardmask 56 which is unpatterned in this cross-sectional view. The opened portion 53 now is completely filled with the sacrificial material 55. In a cross-sectional view which is taken perpendicularly with respect to the view shown in FIG. 6B, the silicon nitride hardmask 56 forms a pattern comprising lines and spaces. Such a cross-sectional view is shown in FIG. 6C which is taken between II and II as can also be seen from FIG. 4. In particular, the openings between adjacent lines of the silicon nitride layer 56 are formed directly above the buried bitlines 4. The cross-sectional view shown in FIG. 6C is taken along a wordline 2. FIG. 6D shows a cross-sectional view between V and V which is taken in the wordline removal region 52 along the direction of the wordlines. As shown in FIG. 6D, the openings between adjacent lines of the silicon nitride hardmask layer 56 are formed so as to uncover portions of the sacrificial material 55. Moreover, after depositing and patterning the silicon nitride hardmask layer 56, in the cross-sectional view between I and I, the view shown in FIG. 6A is obtained.

FIG. 7A shows a plan view of the resulting structure. As shown, the substrate is covered by the silicon nitride bottom hardmask layer 51 in which an opened portion 53 is formed which is filled with the silicon dioxide material 55. In addition, on top of the resulting structure, lines of the silicon nitride top hardmask layer 56 are formed. In particular, the top hardmask layer 56 has been patterned using a mask having a lines/spaces pattern, e.g., the mask which was also used for defining the buried bitlines 4. In the opened portion 53, small segments of the silicon dioxide material 55 are exposed.

FIG. 7B shows, as an alternative, a plan view of the substrate surface wherein the top hardmask layer 56 has been patterned using a photomask having a pattern of elongated holes. Accordingly, segments of the top hardmask layer 56 are removed above the opened portion 53.

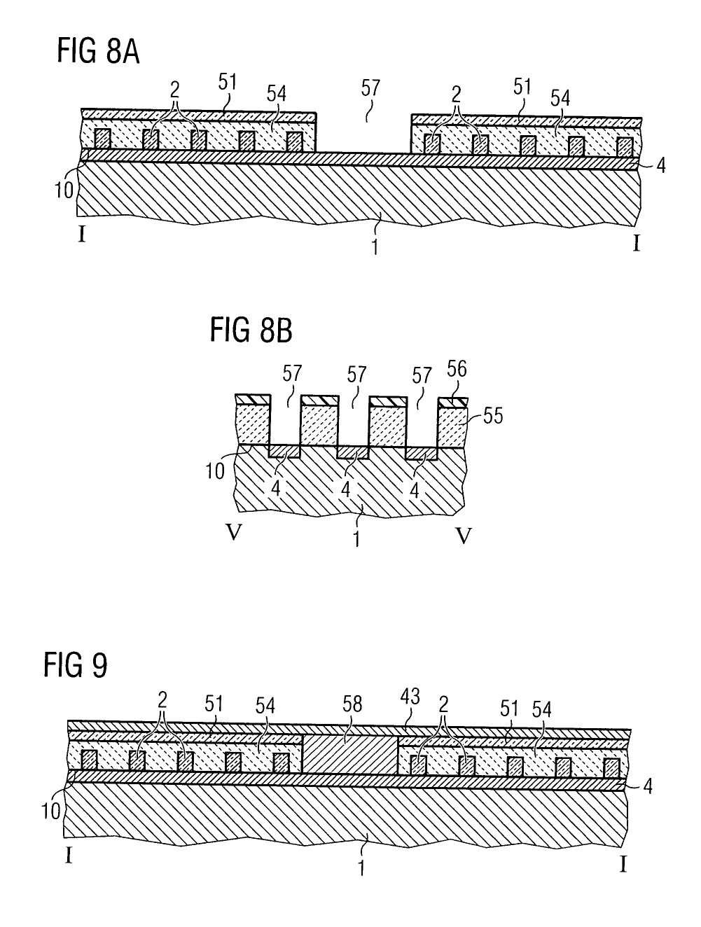

In the next step, an etching step for etching the sacrificial material 55 selectively with respect to the material of the top and bottom hardmask layers 51, 56 is performed. This may be accomplished, e.g., by performing a dry-etching method employing a mixture of C₄F₆/Ar/O₂ or C₄F₈/Ar/O₂ as an etching gas. Alternatively, this may also be accomplished by wet etching using diluted HF. In this manner, the filling of the opening is etched only at those portions which are not covered by any of the top and bottom hardmask layers 51, 56. Accordingly, this etching step is self-aligned in the direction of the bitlines so that a good overlay of the resulting bitline contacts can be obtained. FIG. 8A shows a cross-sectional view of the resulting structure between I and I after performing this etching step. Thereby, the sacrificial material 55 is entirely removed from the opening 53 in a cross-sectional view which is taken along a bitline.

Moreover, in a cross-sectional view which is taken between II and II along a wordline, the etching is stopped by the silicon nitride layer 51, so that no change is made with respect to FIG. 6C.

In addition, as can be seen from FIG. 8B which is taken between V and V, openings 57 are formed in the sacrificial silicon dioxide layer 55, so as to extend to the buried bitlines 4. Moreover, a resulting cross-sectional view which is taken between II and II is identical with the cross-sectional view shown in FIG. 6C, since the silicon nitride hardmask layer 51 acts as an etch stopping layer so that, in this cross-section, no contact openings are formed.

In the next steps, the memory cell array is completed in a manner as is conventional. In particular, a conductive material is filled into the contact openings so as to form the bitline contacts. The surface of the resulting structure is planarized in a manner which is generally known to the person skilled in the art. Moreover, a conductive layer is deposited on top of the resulting substrate and patterned so as to form the metal bitlines 43. In particular, the metal bitlines preferably extend in the direction of the buried bitlines 4. A resulting cross-sectional view is shown in FIG. 9. As shown in FIG. 9, which is taken along a bitline 4, now a conductive material 58 is filled in the opened portion. Moreover, a metal bitline 43 is disposed above the substrate surface in the direction of the bitline 4.

FIG. 10 shows a plan view of the resulting structure. As can be seen, metal bitlines 43 are formed on top of the substrate. In the opened portion 53, the metal bitlines and the bitline contacts 58 are insulated from each other by the sacrificial material 55.

As can be taken from FIG. 10, the number of metal bitlines 43 corresponds to the number of implanted bit lines 4. Nevertheless, depending from the memory device to be formed, the number of metal bitlines 43 can as well be different from the number of implanted bitlines 4.

While the invention has been described in detail and with reference to specific embodiments thereof, it will be apparent to one of ordinary skill in the art that various changes and modifications can be made therein without departing from the spirit and scope thereof. Accordingly, it is intended that the present invention covers the modifications and variations of this invention provided they come within the scope of the appended claims and their equivalents.

### LIST OF REFERENCES

1 semiconductor substrate
10 substrate surface
2 wordline
21 storage layer stack
211 SiO₂ layer
212 Si₃N₄ layer
213 SiO₂ layer
22 wordline layer stack
23 stored charge
24 gate electrode
25 channel
4 buried bitline
41 first source/drain region
42 second source/drain region
43 metal bitline
44 bitline contact
51 silicon nitride hardmask
52 wordline removal region
53 opened portion
54 planarizing layer
55 sacrificial material
56 silicon nitride hardmask
57 contact openings
58 conductive material

What is claimed is:

1. A method of forming a memory cell array, comprising:
providing a semiconductor substrate having a surface;
forming a plurality of first conductive lines that run along a first direction;
forming a plurality of second conductive lines above the first conductive lines that run along a second direction that intersects the first direction;
providing a plurality of memory cells, each of the memory cells being at least partially formed in the semiconductor substrate and being accessible by addressing corresponding ones of the first and second conductive lines;
removing at least one of the second conductive lines, thereby forming an opened portion that extends in the second direction;
filling a sacrificial material into the opened portion;
providing a first hardmask layer;
patterning the first hardmask layer, thereby forming a pattern comprising lines and spaces, such that portions of the sacrificial material are uncovered;
etching the uncovered portions of the sacrificial material selectively with respect to the first hardmask layer thereby forming contact openings;
filling the contact openings with a conductive material; and
providing a plurality of third conductive lines connected to the contact openings.

2. The method of claim 1, wherein the first conductive lines correspond to bit lines and the second conductive lines correspond to word lines of the memory cell array.

3. The method of claim 1, wherein each of the memory cells comprises a transistor comprising: first and second source/drain regions, a channel, a gate electrode, and a storage layer disposed between the channel and the gate electrode.

4. The method of claim 3, wherein each of the first and second source/drain regions forms part of a corresponding first conductive line, and wherein each of the gate electrodes forms part of a corresponding second conductive line.

5. The method of claim 1, wherein providing the plurality of first conductive lines comprises:
providing a covering layer on the substrate surface;
patterning the covering layer using a bitline mask having a lines/spaces pattern such that lines of the substrate surface are uncovered; and
performing an ion implantation step, thereby doping the uncovered lines of the substrate.

6. The method of claim 5, wherein the bitline mask patterns the first hardmask layer, thereby forming the pattern comprising lines and spaces.

7. The method of claim 1, wherein the material of the first hardmask comprises silicon nitride.

8. The method of claim 1, wherein the sacrificial material comprises silicon dioxide.

9. The method of claim 1, wherein removing at least one of the second conductive lines comprises:
providing a second hardmask layer that covers the second conductive lines;
patterning the second hardmask layer such that the at least one of the second conductive lines is uncovered; and
performing an etching step, thereby removing the at least one of the second conductive lines.

10. The method of claim 9, wherein the first and the second hardmask layers are of the same material.

11. The method of claim 9, wherein the first conductive lines correspond to bit lines and the second conductive lines correspond to word lines of the memory cell array.

12. The method of claim 9, wherein each of the memory cells, comprises a transistor comprising: first and second source/drain regions, a channel, a gate electrode and a storage layer disposed between the channel and the gate electrode.

13. The method of claim 12, wherein each of the first and second source/drain regions forms part of a corresponding first conductive line, and wherein each of the gate electrodes forms part of a corresponding second conductive line.

14. The method of claim 9, wherein providing the plurality of first conductive lines, comprises:
providing a covering layer on the substrate surface;
patterning the covering layer using a bitline mask having a lines/spaces pattern such that lines of the substrate surface are uncovered; and
performing an ion implantation step, thereby doping the uncovered lines of the substrate.

15. The method of claim 14, wherein the bitline mask patterns the first hardmask layer, thereby forming the pattern comprising lines and spaces.

16. The method of claim 9, wherein the material of the first hardmask comprises silicon nitride.

17. The method of claim 9, wherein the sacrificial material comprises silicon dioxide.
